(19) United States
(12) Patent Application Publication
(10) Pub. No.: US 2026/0341944 A1
(43) Pub. Date: Oct. 29, 2026

(54) HIGH-FREQUENCY SIGNAL TRANSMISSION LINE AND ELECTRONIC DEVICE

(71) Applicant: Murata Manufacturing Co., Ltd., Nagaokakyo-shi, Kyoto-fu (JP)

(72) Inventor: Masanori OKAMOTO, Nagaokakyo-shi (JP)

(21) Appl. No.: 19/697,641

(22) Filed: Jun. 4, 2026

Related U.S. Application Data
(63) Continuation of application No. PCT/JP2024/039621, filed on Nov. 7, 2024.

(30) Foreign Application Priority Data
Dec. 6, 2023 (JP) 2023-206246

(51) Int. Cl. H01P 3/08

(52) U.S. Cl. CPC H01P 3/081

(57) ABSTRACT

A high-frequency signal transmission line includes a resin stacked portion in which a first resin layer and a second resin layer are stacked, a signal conductor pattern on the first resin layer, and a ground conductor layer facing the signal conductor pattern with a portion or an entirety of the resin stacked portion interposed therebetween. The Young's modulus of the second resin layer is lower than the Young's modulus of the first resin layer. An opening is located in the first resin layer at least at a position along the signal conductor pattern in the resin stacked portion, so that a hollow portion is provided in the resin stacked portion at the opening.

### CROSS REFERENCE TO RELATED APPLICATIONS

This application claims the benefit of priority to Japanese Patent Application No. 2023-206246 filed on Dec. 6, 2023 and is a Continuation Application of PCT Application No. PCT/JP2024/039621 filed on Nov. 7, 2024. The entire contents of each application are hereby incorporated herein by reference.

### BACKGROUND OF THE INVENTION

### 1. Field of the Invention

The present invention relates to high-frequency signal transmission lines and electronic devices including the same.

### 2. Description of the Related Art

International Publication WO 2022/114092 A discloses a transmission line having a suspended structure in which a signal line is located in a resin layer and hollow portions are formed above and below the signal line. In addition, a structure is illustrated in which a resin layer is disposed between an upper hollow portion and an upper ground conductor layer, and a resin layer is disposed between a lower hollow portion and a lower ground conductor layer.

### SUMMARY OF THE INVENTION

In the high-frequency signal transmission line described in International Publication WO 2022/114092 A, when stress is applied from the outside, a hollow portion not filled with a resin is easily deformed. As a result, the vicinity of the hollow portion of the ground conductor layer may be deformed. For example, when a stress exceeding a specified value is applied from the outside of the high-frequency signal transmission line in the direction of the hollow portion, the ground conductor layer is recessed in the direction of the hollow portion. Such deformation of the ground conductor layer near the hollow portion deteriorates electrical characteristics.

Therefore, example embodiments of the present invention provide high-frequency signal transmission lines that achieve enhanced resistance to stress applied from the outside and stable electrical characteristics, and electronic devices each including a high-frequency signal transmission line.

A high-frequency signal transmission line according to an example embodiment of the present disclosure includes a ground conductor layer, a first resin layer, a second resin layer, and a signal conductor pattern, in which the ground conductor layer, the first resin layer, the second resin layer, and the signal conductor pattern are stacked in this order, and a hollow portion is present between the signal conductor pattern and the second resin layer in a direction of the stacking, and the first resin layer and the second resin layer are different in material, and a Young's modulus of the second resin layer is lower than a Young's modulus of the first resin layer.

According to example embodiments of the present invention, it is possible to provide high-frequency signal transmission lines each having high resistance to stress applied from the outside and stable electrical characteristics, and electronic devices including the high-frequency signal transmission lines.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view (upper portion) illustrating a high-frequency signal transmission line 101 according to a first example embodiment, and is a longitudinal cross-sectional view (lower portion) of a one-dot chain line portion.

FIG. 2 is a diagram illustrating stress in the vicinity of the hollow portion HP when stress is applied from the outside of the high-frequency signal transmission line 101.

FIG. 3 is a partial plan view (upper portion) of a high-frequency signal transmission line 102 according to a second example embodiment, and is a longitudinal cross-sectional view (lower portion) of a one-dot chain line portion in the upper portion of FIG. 3.

FIG. 4 is a plan view (upper portion) of a high-frequency signal transmission line 103 according to a third example embodiment, and is a longitudinal cross-sectional view (lower portion) of a one-dot chain line portion in the upper portion of FIG. 4.

FIG. 5 is a plan view (upper portion) of a high-frequency signal transmission line 104 according to a fourth example embodiment, and is a longitudinal cross-sectional view (lower portion) of a one-dot chain line portion in the upper portion of FIG. 5.

FIG. 6 is a plan view before layers of the high-frequency signal transmission line 104 are stacked.

FIG. 7 is a cross-sectional view of layers of the high-frequency signal transmission line 104 before stacking, taken along a one-dot chain line in FIG. 6.

FIG. 8 is a diagram illustrating stress in the vicinity of the hollow portion HP when stress is applied from the outside of the high-frequency signal transmission line 104.

FIG. 9 is a partial plan view (upper portion) in the middle of manufacturing the high-frequency signal transmission line 104 according to the fourth example embodiment, and is a longitudinal cross-sectional view (lower portion) of a one-dot chain line portion in the upper portion of FIG. 9.

FIG. 10 is a cross-sectional view of the high-frequency signal transmission line 104.

FIG. 11 is a longitudinal cross-sectional view of a high-frequency signal transmission line 105 according to a fifth example embodiment of the present invention.

FIG. 12 is a longitudinal cross-sectional view of a high-frequency signal transmission line 106 according to a sixth example embodiment of the present invention.

FIG. 13 is a longitudinal cross-sectional view of a high-frequency signal transmission line 107 according to a seventh example embodiment of the present invention.

FIG. 14 is a longitudinal cross-sectional view of a high-frequency signal transmission line 108 according to an eighth example embodiment of the present invention.

FIG. 15 is a cross-sectional view illustrating a process of manufacturing the high-frequency signal transmission line 108.

FIG. 16 is a longitudinal cross-sectional view of a high-frequency signal transmission line 108A configured by forming a resist film on the high-frequency signal transmission line 108 illustrated in FIG. 14.

FIG. 17 is a longitudinal cross-sectional view of a high-frequency signal transmission line 109 according to a ninth example embodiment of the present invention.

### DETAILED DESCRIPTION OF THE EXAMPLE EMBODIMENTS

Hereinafter, a plurality of example embodiments of the present invention will be shown with some specific examples with reference to the drawings. In each figure, the same elements, components, portions, features, etc., are designated by the same reference signs. In consideration of the description of the main points or ease of understanding, the example embodiment is divided into a plurality of example embodiments for convenience of description, but partial replacement or combination of configurations shown in different example embodiments is possible. In second and subsequent example embodiments, description of matters common to a first example embodiment will be omitted, and only different points will be described. In particular, similar functions and effects obtained by the same configuration will not be sequentially described for each example embodiment.

In the first example embodiment, an example of a microstrip-line high-frequency signal transmission line will be described.

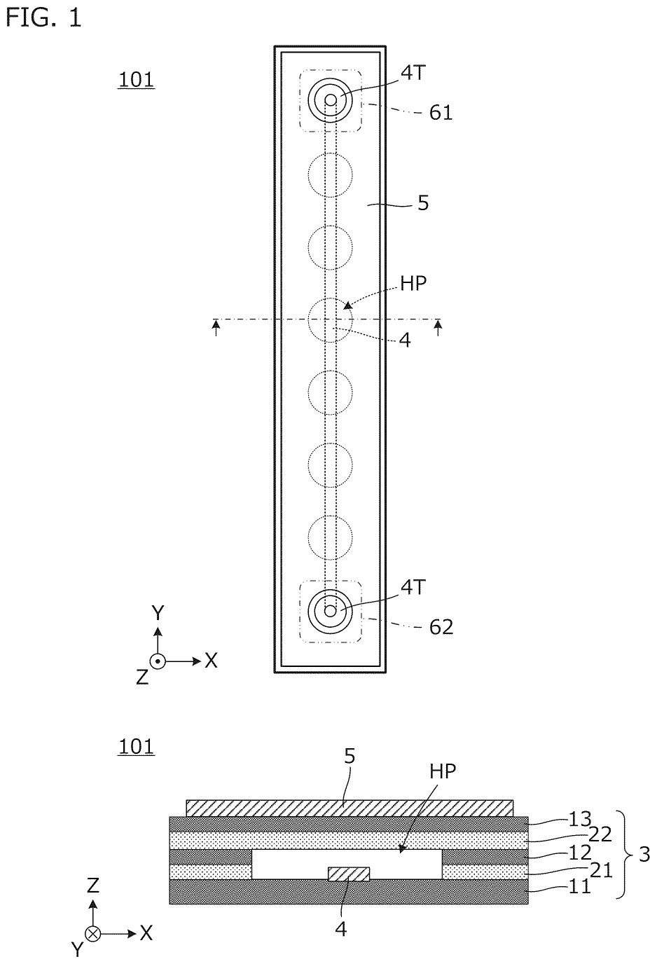

An upper portion of FIG. 1 is a plan view of a high-frequency signal transmission line 101 according to the first example embodiment, and a lower portion of FIG. 1 is a longitudinal cross-sectional view of a portion indicated by a one-dot chain line in the upper portion of FIG. 1. In the cross-sectional view, a line appearing in the cross section (appearing by cutting) is drawn, and illustration of a line existing behind the cross section is omitted. This also applies to each example embodiment described below.

Although a single high-frequency signal transmission line 101 is illustrated in FIG. 1, a large number of high-frequency signal transmission lines continuous in the plane direction are manufactured until the final process at the time of manufacturing, and are separated into the high-frequency signal transmission lines in the final process. This also applies to each example embodiment described below.

The high-frequency signal transmission line 101 includes a resin stacked portion 3, a signal conductor pattern 4, and a ground conductor layer 5.

The resin stacked portion 3 is a portion where first resin layers 11, 12, and 13 and second resin layers 21 and 22 are stacked. The signal conductor pattern 4 is located on the upper surface of the first resin layer 11. The ground conductor layer 5 is stacked on the upper surface of the first resin layer 13. That is, the signal conductor pattern 4 and the ground conductor layer 5 face each other with a portion of the resin stacked portion 3 interposed therebetween.

A circular opening is located in the first resin layer 12 and the second resin layer 21. When expressed by the shape in the drawing, this opening is circular as viewed in the stacking direction of the first resin layers 11, 12, and 13 and the second resin layers 21 and 22.

As described above, since the opening is provided in the first resin layer 12 at the position along the signal conductor pattern 4 in the resin stacked portion 3, a hollow portion HP is provided in the resin stacked portion 3 at the opening. In particular, in the present example embodiment, the hollow portion HP in which the first resin layer 12 and the second resin layer 22 are not in contact with the signal conductor pattern 4 is provided.

As described above, the high-frequency signal transmission line 101 includes the ground conductor layer 5, the first resin layer 13, the second resin layer 22, and the signal conductor pattern 4, and the ground conductor layer 5, the first resin layer 13, the second resin layer 22, and the signal conductor pattern 4 are stacked in this order, and the hollow portion HP exists between the signal conductor pattern 4 and the second resin layer 22 in a direction of the stacking.

Note that the present invention is not limited to the present example embodiment, and in the present invention, the “stacking direction” does not mean the direction of the stacking order of the layers at the time of manufacturing, but means the direction of stacking of the layers in the illustrated state.

As illustrated in the upper portion of FIG. 1, the high-frequency signal transmission line 101 preferably includes six hollow portions HP, for example. That is, the signal conductor pattern 4 passes through the hollow portion HP at these six locations, for example. The high-frequency signal transmission line 101 acts as a microstrip line including the signal conductor pattern 4, the ground conductor layer 5, a portion of the resin stacked portion 3, and the hollow portion HP.

When the interval between the hollow portions HP is less than about ¼ wavelength of the transmission signal, the periodic change in the characteristic impedance accompanying the change in the relative permittivity around the signal conductor pattern 4 does not cause a problem.

As illustrated in the upper portion of FIG. 1, a signal conductor pattern terminal 4T separated from the ground conductor layer 5 is located on the upper surface of the resin stacked portion 3. An end of the signal conductor pattern 4 is connected to the signal conductor pattern terminal 4T via an interlayer connection conductor. A coaxial connector 61 is mounted on the upper signal conductor pattern terminal 4T, and a coaxial connector 62 is mounted on the lower signal conductor pattern terminal 4T. As described above, the high-frequency signal transmission line 101 is used as a transmission line including coaxial connectors at both ends.

Each of the signal conductor pattern 4 and the ground conductor layer 5 includes, for example, a copper foil. The material of the second resin layers 21 and 22 is, for example, thermoplastic polyimide, fluorine-based resin, or polyolefin-based resin, or the like. The polyolefin-based resin is, for example, styrene, polyethylene, polypropylene, or the like. The material of the first resin layers 11, 12, and 13 is polyimide, liquid crystal polymer, or epoxy resin, or the like. The second resin layers 21 and 22 act as adhesive layers to bond adjacent first resin layers among the first resin layers 11, 12, and 13. That is, the first resin layer 13 and the second resin layer 22 are different in material.

The Young's moduli of the second resin layers 21 and 22 are lower than the Young's moduli of the first resin layers 11, 12, and 13. For example, the Young's moduli of the second resin layers 21 and 22 are 1 GPa or less, and the Young's moduli of the first resin layers 11, 12, and 13 are 2 to 5 GPa. That is, the Young's modulus of the second resin layer 22 is lower than the Young's modulus of the first resin layer 13.

The “Young's modulus” is a ratio of stress to strain, and is also expressed as a “Young's coefficient” or a “longitudinal elastic modulus”.

A relative permittivity of the second resin layer is lower than a relative permittivity of the first resin layer. For example, the relative permittivity of the second resin layers 21 and 22 is about 2.0 to about 2.5, and the relative permittivity of the first resin layers 11, 12, and 13 is about 2.5 to about 3.5, for example. That is, the relative permittivity of the second resin layer 22 is lower than the relative permittivity of the first resin layer 13.

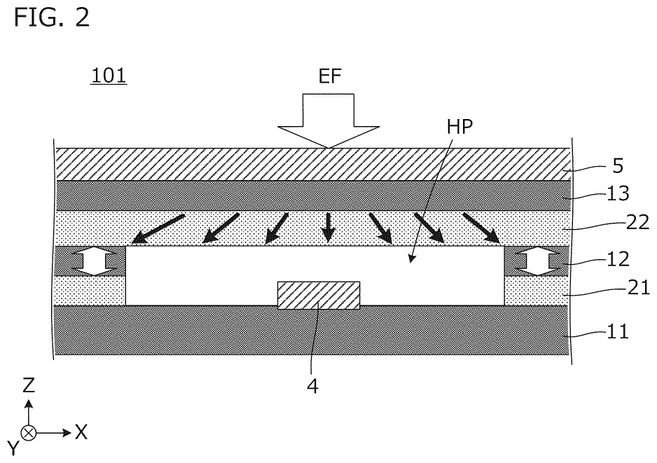

FIG. 2 is a diagram illustrating stress in the vicinity of the hollow portion HP when stress is applied from the outside of the high-frequency signal transmission line 101. When the stress EF is applied from the outside of the high-frequency signal transmission line 101 toward the hollow portion HP, the first resin layer 13 having a relatively high Young's modulus outside the hollow portion disperses the stress in a wide range. The first resin layer 12 under the second resin layer 22 receives a weak stress dispersed by the second resin layer 22. As described above, the second resin layer 22 absorbs stress, and as a result, deformation such as deflection and receding of the ground conductor layer 5 is reduced or prevented. Therefore, the interval between the ground conductor layer 5 and the signal conductor pattern 4 is kept stable.

In short, the above-described action means that the stress applied to the ground conductor layer 5 is dispersed by the first resin layer 13 having a high Young's modulus and absorbed by the second resin layer 22 having a low Young's modulus, whereby the deformation of the ground conductor layer 5 is reduced or prevented.

In addition, according to the present example embodiment, since the hollow portion HP exists around the signal conductor pattern of the high-frequency signal transmission line, the dielectric loss is reduced. That is, since the hollow portion HP is air, both the dielectric loss tangent and the dielectric constant are smaller than those of the resin of the resin stacked portion 3, and the dielectric loss of the high-frequency signal transmission line is reduced. The same functions and effects apply to each example embodiment described below.

For example, the entire resin stacked portion 3 may be sandwiched between the signal conductor pattern 4 and the ground conductor layer by providing the signal conductor pattern 4 not on the upper surface but on the lower surface of the first resin layer 11.

In the second example embodiment, an example of a high-frequency signal transmission line in which a ground conductor exists on a side portion of a signal conductor pattern will be described.

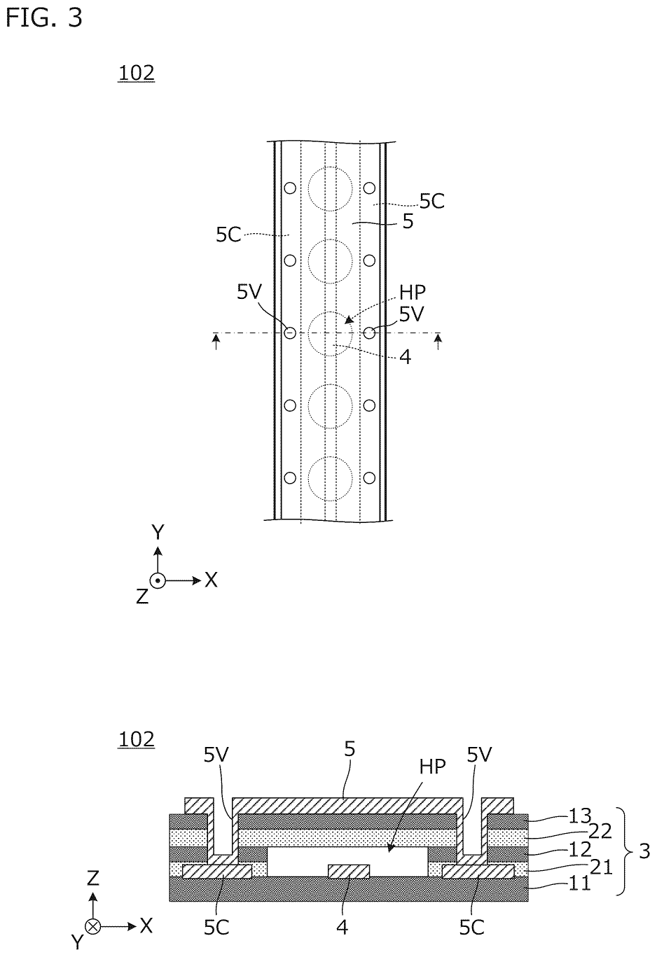

The upper portion of FIG. 3 is a partial plan view of the high-frequency signal transmission line 102 according to the second example embodiment, and the lower portion of FIG. 3 is a longitudinal cross-sectional view of a portion indicated by a one-dot chain line in the upper portion of FIG. 3.

The high-frequency signal transmission line 102 includes a resin stacked portion 3, a signal conductor pattern 4, a ground conductor layer 5, a ground conductor pattern 5C, and an interlayer connection conductor 5V.

The resin stacked portion 3 is a portion where first resin layers 11, 12, and 13 and second resin layers 21 and 22 are stacked. The signal conductor pattern 4 and the ground conductor pattern 5C are located on the upper surface of the first resin layer 11. The ground conductor layer 5 is stacked on the upper surface of the first resin layer 13. That is, the signal conductor pattern 4 and the ground conductor layer 5 face each other with a portion of the resin stacked portion 3 interposed therebetween. An interlayer connection conductor 5V is located in the resin stacked portion 3. These interlayer connection conductors 5V electrically connect the ground conductor layer 5 and the ground conductor pattern 5C.

In the first resin layer 12 and the second resin layer 21, circular openings are provided as viewed in the stacking direction of the first resin layers 11, 12, and 13 and the second resin layers 21 and 22.

As described above, since the opening is located in the first resin layer 12 at the position along the signal conductor pattern 4 in the resin stacked portion 3, a hollow portion HP is provided in the resin stacked portion 3 at the opening. In particular, in the present example embodiment, the hollow portion HP in which the first resin layer 12 and the second resin layer 22 are not in contact with the signal conductor pattern 4 is provided.

As illustrated in the lower portion of FIG. 3, a plurality of hollow portions HP are located in the high-frequency signal transmission line 102. That is, the signal conductor pattern 4 passes through these hollow portions HP.

Each of the signal conductor pattern 4, the ground conductor pattern 5C, and the ground conductor layer 5 includes, for example, a copper foil. The materials of the first resin layers 11, 12, and 13 and the materials of the second resin layers 21 and 22 are the same as those in the example described in the first example embodiment. The second resin layers 21 and 22 act as adhesive layers to bond adjacent first resin layers among the first resin layers 11, 12, and 13.

Similarly to the example described in the first example embodiment, the Young's moduli of the second resin layers 21 and 22 are lower than the Young's moduli of the first resin layers 11, 12, and 13.

Also in the high-frequency signal transmission line 102 of the present example embodiment, similarly to the high-frequency signal transmission line 101 described in the first example embodiment, the ground conductor layer 5, the first resin layer 13, the second resin layer 22, and the signal conductor pattern 4 are stacked in this order, the hollow portion HP is present between the signal conductor pattern 4 and the second resin layer 22 in a direction of the stacking, the materials of the first resin layer 13 and the second resin layer 22 are different, and the Young's modulus of the second resin layer 22 is lower than the Young's modulus of the first resin layer 13.

The stress in the vicinity of the hollow portion when the stress is applied from the outside of the high-frequency signal transmission line 102 is as described in the first example embodiment, and deformation such as deflection and recess of the ground conductor layer 5 is reduced or prevented. Therefore, the interval between the ground conductor layer 5 and the signal conductor pattern 4 is kept stable, and the electrical characteristics of the high-frequency signal transmission line can be kept constant.

Like the high-frequency signal transmission line 102 illustrated in the present example embodiment, a high-frequency signal transmission line according to an example embodiment of the present invention may further include a ground conductor layer (5C) in the line width direction of the signal conductor pattern (4).

In the third example embodiment, an example of a triplate type of a strip-line-type high-frequency signal transmission line in which a hollow portion HP exists above a signal conductor pattern 4 will be described.

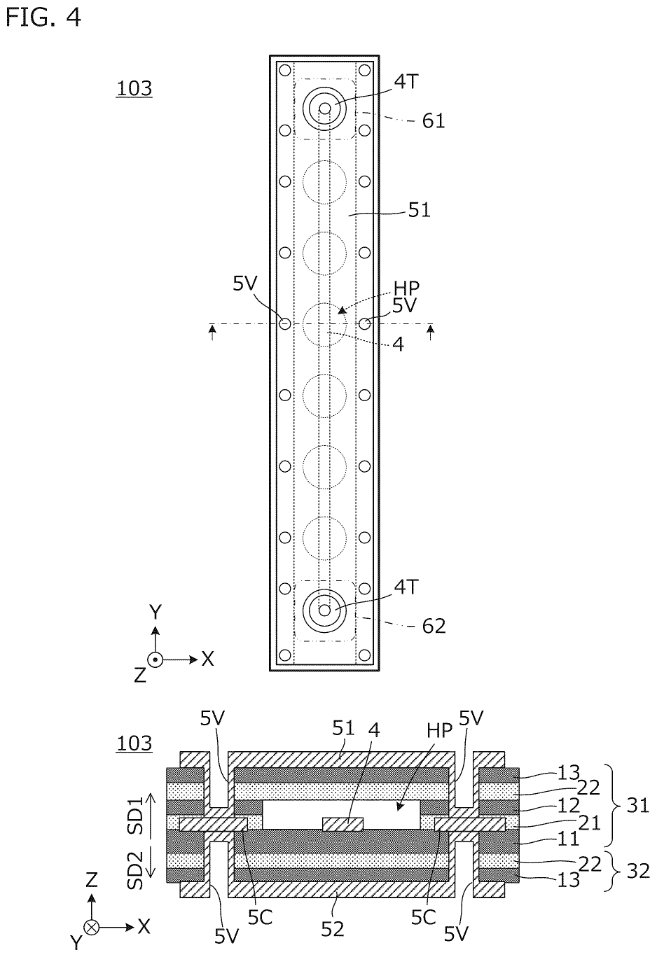

The upper portion of FIG. 4 is a plan view of the high-frequency signal transmission line 103 according to the third example embodiment, and the lower portion of FIG. 4 is a longitudinal cross-sectional view of a portion indicated by a one-dot chain line in the upper portion of FIG. 4.

The high-frequency signal transmission line 103 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, and 13 and the upper second resin layers 21 and 22 are stacked. The lower resin stacked portion 32 is a portion where the lower first resin layer 13 and the lower second resin layer 22 are stacked. That is, the resin stacked portion includes the upper resin stacked portion 31 stacked in a first stacking direction SD1 in the direction of stacking of the first resin layer and the second resin layer, and the lower resin stacked portion 32 configured in a second stacking direction SD2 opposite to the first stacking direction SD1.

The signal conductor pattern 4 is located on the upper surface of the first resin layer 11. A first ground conductor layer 51 is stacked on the upper surface of the upper first resin layer 13. A second ground conductor layer 52 is stacked on the lower surface of the lower first resin layer 13. That is, the signal conductor pattern 4 faces the first ground conductor layer 51 and the second ground conductor layer 52 with the upper resin stacked portion 31 and the lower resin stacked portion 32 interposed therebetween.

A circular opening is located in the first resin layer 12 and the second resin layer 21. When expressed by the shape in the drawing, this opening is circular as viewed in the stacking direction of the first resin layers 11, 12, and 13 and the second resin layers 21 and 22.

As described above, since the opening is located in the first resin layer 12 at the position along the signal conductor pattern 4 in the upper resin stacked portion 31, a hollow portion HP is provided in the upper resin stacked portion 31 at the opening. In particular, in the present example embodiment, the hollow portion HP in which the first resin layer 12 and the second resin layer 22 are not in contact with the signal conductor pattern 4 is provided.

In the high-frequency signal transmission line 103 of the present example embodiment, the first ground conductor layer 51, the upper first resin layer 13, the upper second resin layer 22, and the signal conductor pattern 4 are stacked in this order, the hollow portion HP is present between the signal conductor pattern 4 and the upper second resin layer 22 in a direction of the stacking, the materials of the upper first resin layer 13 and the upper second resin layer 22 are different, and the Young's modulus of the upper second resin layer 22 is lower than the Young's modulus of the upper first resin layer 13.

As illustrated in the upper portion of FIG. 4, the high-frequency signal transmission line 103 preferably includes six hollow portions HP, for example. That is, the signal conductor pattern 4 passes through the hollow portion HP at these six locations, for example. The high-frequency signal transmission line 103 acts as a strip line including the signal conductor pattern 4, the first ground conductor layer 51, the second ground conductor layer 52, the upper resin stacked portion 31, the lower resin stacked portion 32, and the hollow portion HP.

Also in the present example embodiment, similarly to the first and second example embodiments, when stress is applied from the outside of the high-frequency signal transmission line 103 in the direction of the hollow portion HP, the first resin layer 13 having a relatively high Young's modulus on the outer side disperses the stress in a wide range, so that deformation such as deflection and recess of the first ground conductor layer 51 is reduced or prevented. Therefore, the interval between the first ground conductor layer 51 and the signal conductor pattern 4 is kept stable.

In the fourth example embodiment, an example of a strip-line-type high-frequency signal transmission line in which hollow portions HP exist above and below a signal conductor pattern 4 will be described.

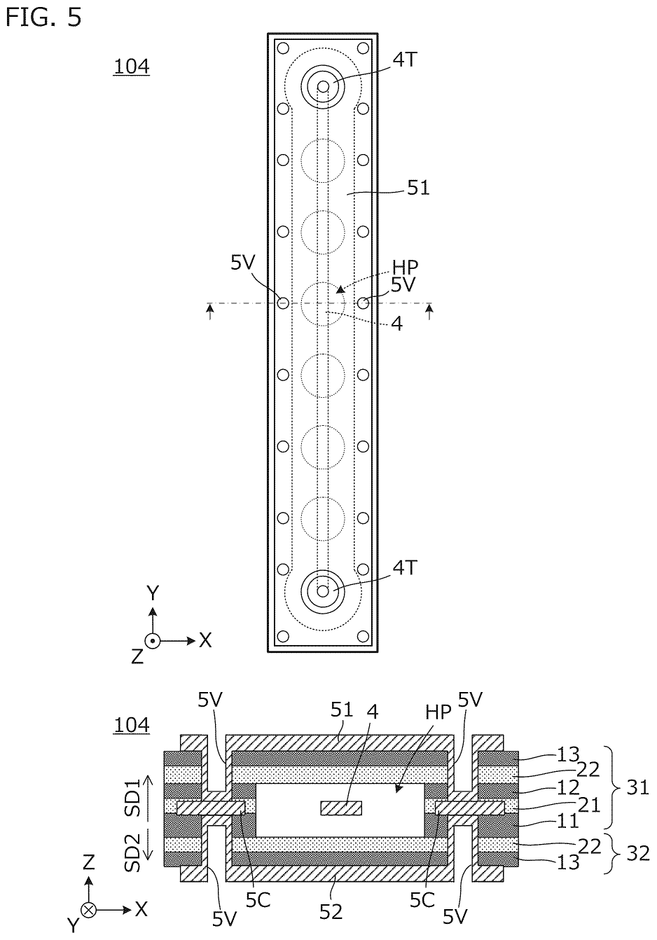

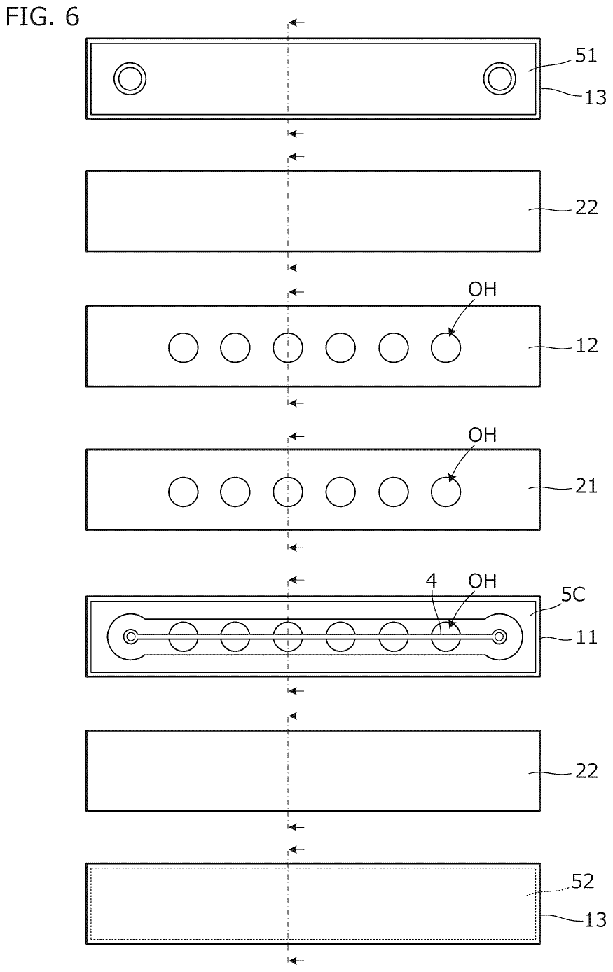

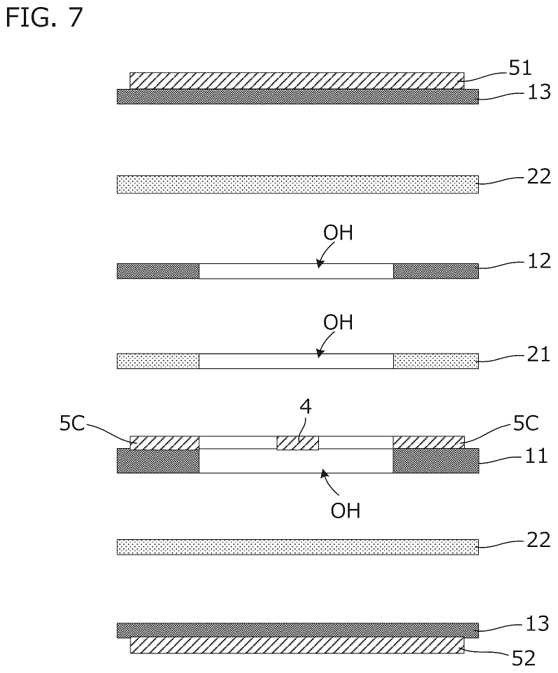

The upper portion of FIG. 5 is a plan view of the high-frequency signal transmission line 104 according to the fourth example embodiment, and the lower portion of FIG. 5 is a longitudinal cross-sectional view of a portion indicated by a one-dot chain line in the upper portion of FIG. 5. FIG. 6 is a plan view before stacking layers of the high-frequency signal transmission line 104. FIG. 7 is a cross-sectional view of layers of the high-frequency signal transmission line 104 before stacking, taken along a one-dot chain line in FIG. 6. Since FIGS. 6 and 7 are in a state before stacking, the interlayer connection conductor 5V described later does not appear in these drawings.

The high-frequency signal transmission line 104 according to the present example embodiment includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, and 13 and the upper second resin layers 21 and 22 are stacked. The lower resin stacked portion 32 is a portion where the lower first resin layer 13 and the lower second resin layer 22 are stacked. That is, the resin stacked portion includes the upper resin stacked portion 31 stacked in a first stacking direction SD1 in the direction of stacking of the first resin layer and the second resin layer, and the lower resin stacked portion 32 stacked in a second stacking direction SD2 opposite to the first stacking direction SD1.

The signal conductor pattern 4 is located on the upper surface of the first resin layer 11. A first ground conductor layer 51 is stacked on the upper surface of the upper first resin layer 13. A second ground conductor layer 52 is stacked on the lower surface of the lower first resin layer 13.

As illustrated in FIGS. 6 and 7, the first ground conductor layer 51 is located in the upper first resin layer 13, and the second ground conductor layer 52 is located in the lower first resin layer 13. A signal conductor pattern 4 and a ground conductor pattern 5C are located on the first resin layer 11. An opening OH is located in the upper first resin layer 12, the second resin layer 21, and the first resin layer 11.

By stacking the opening OH, the hollow portion HP in which the first resin layers 11 and 12 and the second resin layer 22 are not in contact with the signal conductor pattern 4 is provided. As is clear from comparison with the example illustrated in FIG. 4, the signal conductor pattern 4 includes a portion that is not in contact with the first resin layer 11.

In the high-frequency signal transmission line 104 of the present example embodiment, the first ground conductor layer 51, the upper first resin layer 13, the upper second resin layer 22, and the signal conductor pattern 4 are stacked in this order, and the hollow portion HP is present between the signal conductor pattern 4 and the upper second resin layer 22 in a direction of the stacking. Similarly, the second ground conductor layer 52, the lower first resin layer 13, the lower second resin layer 22, and the signal conductor pattern 4 are stacked in this order, and a hollow portion HP is present between the signal conductor pattern 4 and the lower second resin layer 22 in a direction of the stacking. In addition, the material of the upper first resin layer 13 is different from the material of the upper second resin layer 22, and the Young's modulus of the upper second resin layer 22 is lower than the Young's modulus of the upper first resin layer 13. Similarly, the material of the lower first resin layer 13 is different from the material of the lower second resin layer 22, and the Young's modulus of the lower second resin layer 22 is lower than the Young's modulus of the lower first resin layer 13.

As illustrated in the upper portion of FIG. 5, the high-frequency signal transmission line 104 preferably includes six hollow portions HP, for example. That is, the signal conductor pattern 4 passes through the hollow portion HP at these six locations, for example. The high-frequency signal transmission line 104 acts as a strip line including the signal conductor pattern 4, the first ground conductor layer 51, the second ground conductor layer 52, the upper resin stacked portion 31, the lower resin stacked portion 32, and the hollow portion HP.

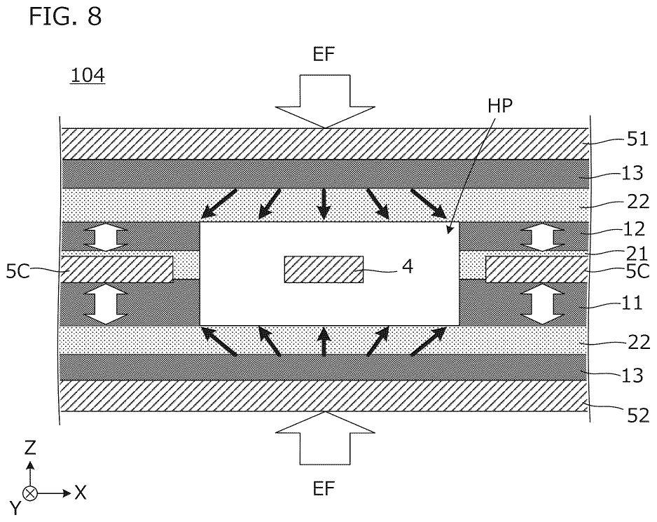

FIG. 8 is a diagram illustrating stress in the vicinity of the hollow portion HP when stress is applied from the outside of the high-frequency signal transmission line 104.

When the stress EF is applied from the outside of the high-frequency signal transmission line 104 toward the hollow portion HP, the first resin layer 13 having a relatively high Young's modulus outside the upper portion of the hollow portion disperses the stress in a wide range. The upper second resin layer 22 absorbs the stress. As described above, the second resin layer 22 absorbs stress, so that deformation such as deflection and recess of the first ground conductor layer 51 is reduced or prevented.

Similarly, the first resin layer 13 having a relatively high Young's modulus located outside the lower portion with respect to the hollow portion HP disperses stress in a wide range. The lower second resin layer 22 absorbs the stress. As described above, the lower second resin layer 22 absorbs stress, so that deformation such as deflection and recess of the second ground conductor layer 52 is reduced or prevented. Therefore, the intervals between the first ground conductor layer 51 and the signal conductor pattern 4 and between the second ground conductor layer 52 and the signal conductor pattern 4 are kept stable.

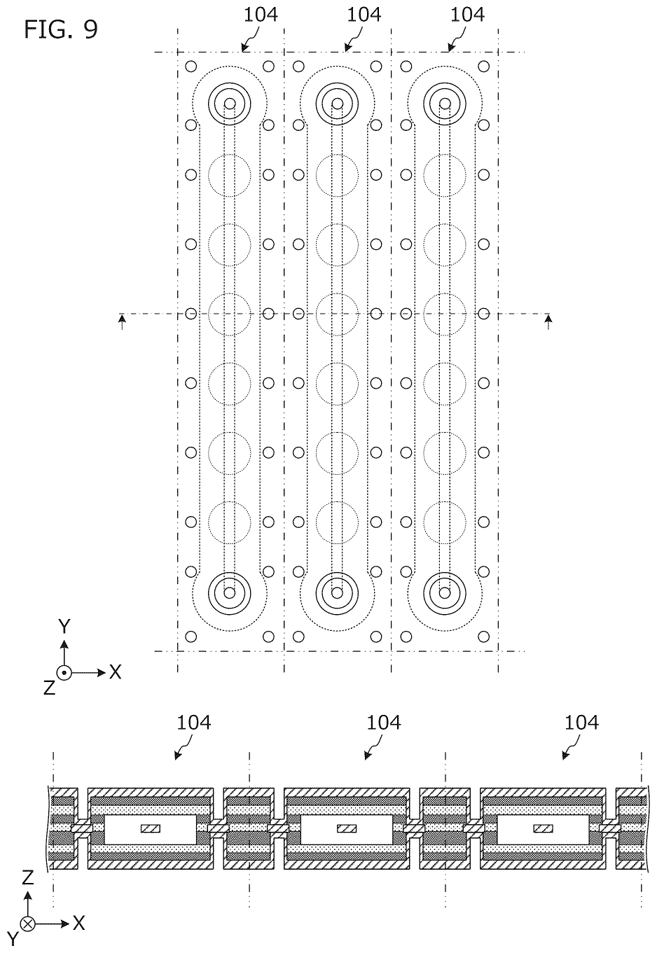

The upper portion of FIG. 9 is a partial plan view in the middle stage of manufacturing the high-frequency signal transmission line 104 according to the present example embodiment, and the lower portion of FIG. 9 is a longitudinal cross-sectional view of a one-dot chain line portion in the upper portion of FIG. 9.

Although the single high-frequency signal transmission line 104 is illustrated in FIG. 5, the single high-frequency signal transmission line 104 is a continuous body of a plurality of high-frequency signal transmission lines in an intermediate stage of manufacturing the single high-frequency signal transmission line. The configuration of the units of the high-frequency signal transmission lines 104 is already as illustrated in FIG. 5.

In FIG. 9, a stacked body including a resin layer, a conductor layer, and the like is cut at vertical and horizontal two-dot chain line portions to be separated into a plurality of high-frequency signal transmission lines 104.

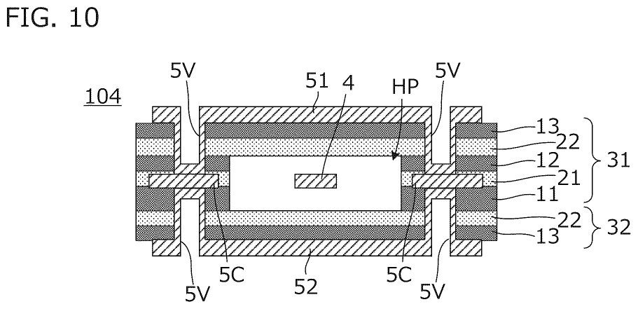

FIG. 10 is a cross-sectional view illustrating a difference in electric field between the high-frequency signal transmission line 104 and the high-frequency signal transmission line as a comparative example thereof. FIG. 10 is a cross-sectional view of the high-frequency signal transmission line 104 according to the present example embodiment.

In the high-frequency signal transmission line 104, the second resin layer 22 having a relative permittivity lower than that of the first resin layer 13 is exposed in a wide area with respect to the hollow portion HP. That is, since the relative permittivity of the second resin layers 22 and 22 at positions close to the signal conductor pattern 4 in the stacking direction is lower than that of the first resin layers 13 and 13, the dielectric loss due to the dielectric in the region with high electric field strength is reduced, thereby preventing deterioration of the transmission characteristics.

In the fifth example embodiment, an example of a strip-line-type high-frequency signal transmission line in which hollow portions HP exist above and below a signal conductor pattern 4 will be described.

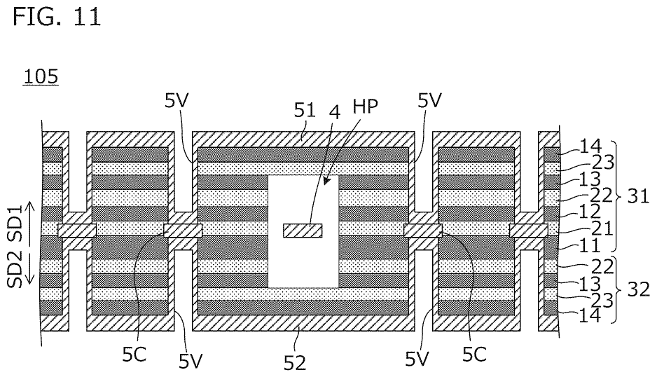

FIG. 11 is a longitudinal cross-sectional view of a high-frequency signal transmission line 105 according to the fifth example embodiment.

The high-frequency signal transmission line 105 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, 13, and 14 and the upper second resin layers 21, 22, and 23 are stacked. The lower resin stacked portion 32 is a portion where the lower first resin layers 13 and 14 and the lower second resin layers 22 and 23 are stacked. That is, the resin stacked portion includes the upper resin stacked portion 31 stacked in a first stacking direction SD1 in the direction of stacking of the first resin layer and the second resin layer, and the lower resin stacked portion 32 stacked in a second stacking direction SD2 opposite to the first stacking direction SD1.

In the high-frequency signal transmission line 105, an upper first resin layer 14, a lower first resin layer 14, an upper second resin layer 23, and a lower second resin layer 23 are added to the high-frequency signal transmission line 104 illustrated in FIG. 5 in the fourth example embodiment.

Circular openings are located in the upper first resin layers 11, 12, and 13, the upper second resin layers 21 and 22, the lower first resin layer 13, and the lower second resin layer 22, respectively. These openings define a hollow portion HP in which the first resin layers 11, 12, and 13 and the second resin layer 22 are not in contact with the signal conductor pattern 4. As is clear from comparison with the example illustrated in FIG. 4, the signal conductor pattern 4 includes a portion that is not in contact with the first resin layer 11.

The second resin layers 21, 22, and 23 act as adhesive layers to bond adjacent first resin layers among the first resin layers 11, 12, 13, and 14.

The Young's moduli of the second resin layers 21, 22, and 23 are lower than the Young's moduli of the first resin layers 11, 12, 13, and 14.

As described above, in the high-frequency signal transmission line 105 of the present example embodiment, the first ground conductor layer 51, the upper first resin layer 14, the upper second resin layer 23, and the signal conductor pattern 4 are stacked in this order, and the hollow portion HP is present between the signal conductor pattern 4 and the upper second resin layer 23 in a direction of the stacking. Similarly, the second ground conductor layer 52, the lower first resin layer 14, the lower second resin layer 23, and the signal conductor pattern 4 are stacked in this order, and a hollow portion HP is present between the signal conductor pattern 4 and the lower second resin layer 23 in a direction of the stacking. The hollow portion HP is continuous with the above-described hollow portion HP. In addition, the material of the upper first resin layer 14 is different from the material of the upper second resin layer 23, and the Young's modulus of the upper second resin layer 23 is lower than the Young's modulus of the upper first resin layer 14. Similarly, the material of the lower first resin layer 14 is different from the material of the lower second resin layer 23, and the Young's modulus of the lower second resin layer 23 is lower than the Young's modulus of the lower first resin layer 14.

According to the present example embodiment, the stress applied to the first ground conductor layer 51 is dispersed by the upper first resin layer 14 having a high Young's modulus and absorbed by the upper second resin layer 23 having a low Young's modulus, so that deformation of the first ground conductor layer 51 is reduced or prevented. Similarly, the stress applied to the second ground conductor layer 52 is dispersed by the lower first resin layer 14 having a high Young's modulus and absorbed by the lower second resin layer 23 having a low Young's modulus, so that deformation of the second ground conductor layer 52 is reduced or prevented.

As in the present example embodiment, the present invention can also be applied to a high-frequency signal transmission line in which three or more second resin layers 21, 22, and 23 are present in an upper portion and two or more second resin layers 22 and 23 are present in a lower portion.

In the sixth example embodiment, an example of a strip-line-type high-frequency signal transmission line in which a hollow portion HP exists above a signal conductor pattern 4 will be described.

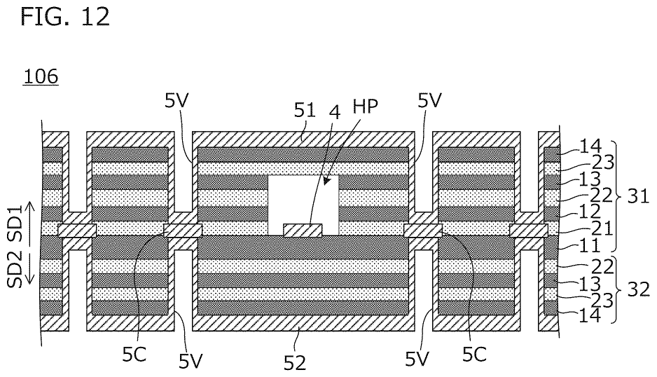

FIG. 12 is a longitudinal cross-sectional view of a high-frequency signal transmission line 106 according to the sixth example embodiment.

The high-frequency signal transmission line 106 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, 13, and 14 and the upper second resin layers 21, 22, and 23 are stacked. The lower resin stacked portion 32 is a portion where the lower first resin layers 13 and 14 and the lower second resin layers 22 and 23 are stacked. That is, the resin stacked portion includes the upper resin stacked portion 31 stacked in a first stacking direction SD1 in the direction of stacking of the first resin layer and the second resin layer, and the lower resin stacked portion 32 configured in a second stacking direction SD2 opposite to the first stacking direction SD1.

A circular opening is located in each of the upper first resin layers 12 and 13 and the upper second resin layer 22.

As described above, since the opening is located in the first resin layers 12 and 13 at the position along the signal conductor pattern 4 in the upper resin stacked portion 31, a hollow portion HP is provided in the upper resin stacked portion 31 at the opening. In particular, in the present example embodiment, the hollow portion HP in which the first resin layer 12, the second resin layer 22, and the first resin layer 13 are not in contact with the signal conductor pattern 4 is provided.

The second resin layers 21, 22, and 23 act as adhesive layers to bond adjacent first resin layers among the first resin layers 11, 12, 13, and 14.

The Young's moduli of the second resin layers 21, 22, and 23 are lower than the Young's moduli of the first resin layers 11, 12, 13, and 14.

As described above, in the high-frequency signal transmission line 106 of the present example embodiment, the first ground conductor layer 51, the upper first resin layer 14, the upper second resin layer 23, and the signal conductor pattern 4 are stacked in this order, the hollow portion HP is present between the signal conductor pattern 4 and the upper second resin layer 23 in a direction of the stacking, the materials of the upper first resin layer 14 and the upper second resin layer 23 are different, and the Young's modulus of the upper second resin layer 23 is lower than the Young's modulus of the upper first resin layer 14.

In the present example embodiment, since the lower portion of the signal conductor pattern 4 is supported by the plurality of resin layers below the signal conductor pattern 4, the interval between the signal conductor pattern 4 and the second ground conductor layer 52 can be maintained in a more stable state.

As in the present example embodiment, the present invention can also be applied to a high-frequency signal transmission line in which three or more second resin layers 21, 22, and 23 and two or more second resin layers 22 and 23 are present.

In the seventh example embodiment, an example of a strip-line-type high-frequency signal transmission line in which the hollow portion HP exists above the signal conductor pattern 4 and the hollow portion HP exists below the first resin layer 11 on which the signal conductor pattern is provided will be described.

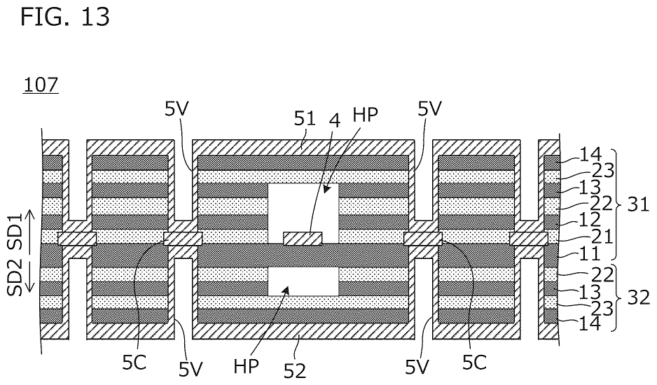

FIG. 13 is a longitudinal cross-sectional view of a high-frequency signal transmission line 107 according to the seventh example embodiment.

The high-frequency signal transmission line 107 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

Circular openings are located in the upper first resin layers 12 and 13 and the upper second resin layers 21 and 22, respectively. As described above, since the opening is located in the first resin layers 12 and 13 at the position along the signal conductor pattern 4 in the upper resin stacked portion 31, a hollow portion HP is provided in the upper resin stacked portion 31 at the opening.

A circular opening is located in each of the lower first resin layer 13 and the lower second resin layer 22. As described above, since the opening is located in the first resin layer 13 at the lower position along the signal conductor pattern 4 in the lower resin stacked portion 32, the hollow portion HP is provided in the lower resin stacked portion 32 at the opening.

The second resin layers 21, 22, and 23 act as adhesive layers to bond adjacent first resin layers among the first resin layers 11, 12, 13, and 14.

The Young's moduli of the second resin layers 21, 22, and 23 are lower than the Young's moduli of the first resin layers 11, 12, 13, and 14.

As described above, in the high-frequency signal transmission line 107 of the present example embodiment, the first ground conductor layer 51, the upper first resin layer 14, the upper second resin layer 23, and the signal conductor pattern 4 are stacked in this order, and the hollow portion HP is present between the signal conductor pattern 4 and the upper second resin layer 23 in a direction of the stacking. Similarly, the second ground conductor layer 52, the lower first resin layer 14, the lower second resin layer 23, and the signal conductor pattern 4 are stacked in this order, and a hollow portion HP is present between the signal conductor pattern 4 and the lower second resin layer 23 in a direction of the stacking. In addition, the material of the upper first resin layer 14 is different from the material of the upper second resin layer 23, and the Young's modulus of the upper second resin layer 23 is lower than the Young's modulus of the upper first resin layer 14. Similarly, the material of the lower first resin layer 14 is different from the material of the lower second resin layer 23, and the Young's modulus of the lower second resin layer 23 is lower than the Young's modulus of the lower first resin layer 14.

According to the present example embodiment, the stress applied to the first ground conductor layer 51 is dispersed by the upper first resin layer 14 having a high Young's modulus and absorbed by the upper second resin layer 23 having a low Young's modulus, so that deformation of the first ground conductor layer 51 is reduced or prevented. Similarly, the stress applied to the second ground conductor layer 52 is dispersed by the lower first resin layer 14 having a high Young's modulus and absorbed by the lower second resin layer 23 having a low Young's modulus, so that deformation of the second ground conductor layer 52 is reduced or prevented.

Even when the hollow portion (the hollow portion HP in the lower portion in FIG. 13) where the signal conductor pattern 4 is not exposed is provided as in the present example embodiment, deformation such as deflection or recess of the second ground conductor layer 52 near the hollow portion with respect to external stress is reduced or prevented.

Further, in the present example embodiment, since the signal conductor pattern 4 is supported by the first resin layer 11 even at the place where the lower hollow portion exists, the first resin layer 11 acts as a rigid layer, and the interval between the signal conductor pattern 4 and the first ground conductor layer 51 and the second ground conductor layer 52 can be maintained in a more stable state.

In the eighth example embodiment, a high-frequency signal transmission line including a protruding portion in an interlayer connection conductor electrically connecting a first ground conductor layer and a second ground conductor layer will be exemplified.

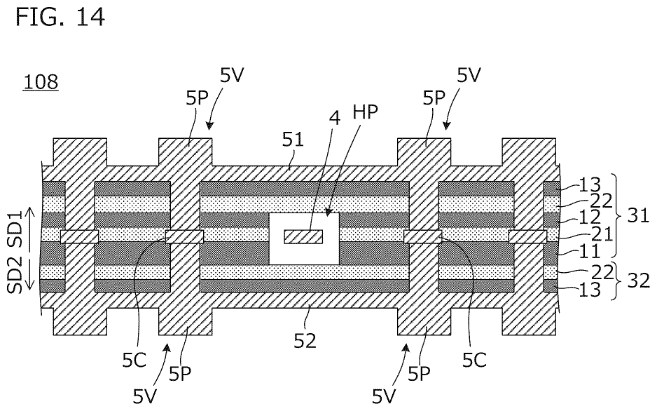

FIG. 14 is a longitudinal cross-sectional view of a high-frequency signal transmission line 108 according to the eighth example embodiment. The high-frequency signal transmission line 108 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

In the high-frequency signal transmission line 104 illustrated in FIG. 5, the interlayer connection conductor 5V is formed by forming a conductor plating film on the inner surface of the opening located in each resin layer between the first ground conductor layer 51 and the ground conductor pattern 5C, but in the high-frequency signal transmission line 108 illustrated in FIG. 14, the interlayer connection conductor 5V is formed by filling the opening located in each resin layer between the first ground conductor layer 51 and the ground conductor pattern 5C with a conductor, and the opening located in each resin layer between the second ground conductor layer 52 and the ground conductor pattern 5C is filled with a conductor to provide the interlayer connection conductor 5V.

The upper interlayer connection conductor 5V electrically connected to the first ground conductor layer 51 includes a protruding portion 5P protruding from the first ground conductor layer 51 to the outside in the first stacking direction SD1. The lower interlayer connection conductor 5V electrically connected to the second ground conductor layer 52 includes a protruding portion 5P protruding from the second ground conductor layer 52 to the outside in the second stacking direction SD2.

Even if an external force is applied to the high-frequency signal transmission line 108 on a wide surface, the protruding portion 5P receives the external force, so that no stress is applied immediately above the hollow portion HP, and deformation of the first ground conductor layer 51 above the hollow portion HP and the second ground conductor layer 52 below the hollow portion HP is effectively reduced or prevented.

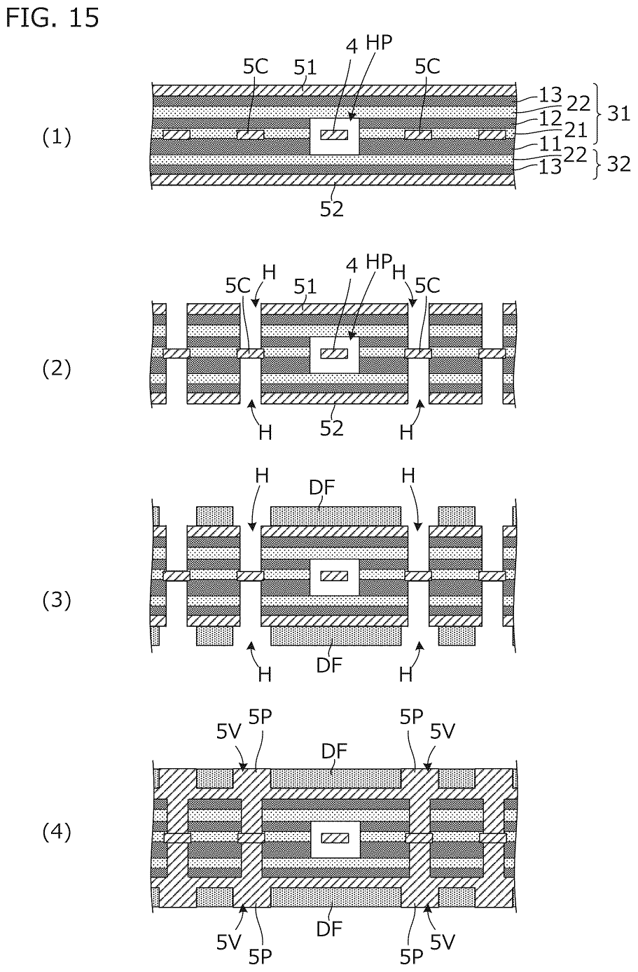

FIG. 15 is a cross-sectional view illustrating a manufacturing process of the high-frequency signal transmission line 108. In the process illustrated in (1) of FIG. 15, a stacked body of the first resin layers 11, 12, and 13, the second resin layers 21 and 22, the signal conductor pattern 4, the ground conductor pattern 5C, the first ground conductor layer 51, and the second ground conductor layer 52 is provided.

The first ground conductor layer 51 is attached to the upper first resin layer 13. The second ground conductor layer 52 is attached to the lower first resin layer 13. Openings to provide the hollow portion HP are located in the first resin layers 11 and 12. The second resin layer 21 is applied to the upper surface of the first resin layer 11. The upper second resin layer 22 is applied to the lower surface of the upper first resin layer 13. The lower second resin layer 22 is applied to the upper surface of the lower first resin layer 13. These layers are stacked and heated and pressurized to form the stacked body.

In the step illustrated in (2) of FIG. 15, a hole H to expose the ground conductor pattern 5C is formed by laser processing from the outer surface of the stacked body.

In the step illustrated in (3) in FIG. 15, a dry film DF is attached to both surfaces of the stacked body, and a hole larger than the hole diameter of the hole H is located in the dry film DF.

In the step illustrated in (4) of FIG. 15, copper-filled plating (via fill plating) is applied inside the holes H, and the entire holes are filled with copper.

In the subsequent step, the dry film DF is peeled off. As a result, the high-frequency signal transmission line 108 illustrated in FIG. 14 is obtained. Thereafter, the high-frequency signal transmission lines are divided into individual high-frequency signal transmission lines 108.

According to the present example embodiment, even when an external force is applied to the high-frequency signal transmission line 108 on a wide surface, no stress is applied immediately above the hollow portion HP, and deformation of the first ground conductor layer 51 in the upper portion of the hollow portion HP and the second ground conductor layer 52 in the lower portion of the hollow portion HP is effectively reduced or prevented.

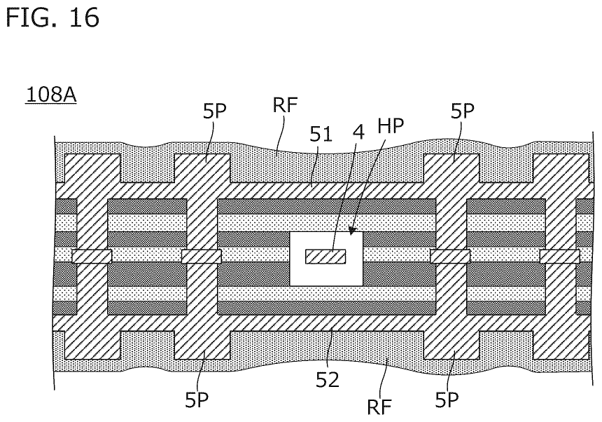

FIG. 16 is a longitudinal cross-sectional view of a high-frequency signal transmission line 108A formed by forming a resist film on the high-frequency signal transmission line 108 illustrated in FIG. 14. The resist film RF illustrated in FIG. 16 is a resist film that is cured after being applied to the front and back surfaces of the high-frequency signal transmission line 108 illustrated in FIG. 14. As described above, since the resist film RF protrudes at the protruding portion 5P of the interlayer connection conductor, even if an external force is applied to the high-frequency signal transmission line 108A on a wide surface, no stress is applied immediately above the hollow portion HP, and deformation of the first ground conductor layer 51 above the hollow portion HP and the second ground conductor layer 52 below the hollow portion HP is effectively reduced or prevented.

In the ninth example embodiment, a high-frequency signal transmission line including a plurality of transmission lines will be exemplified.

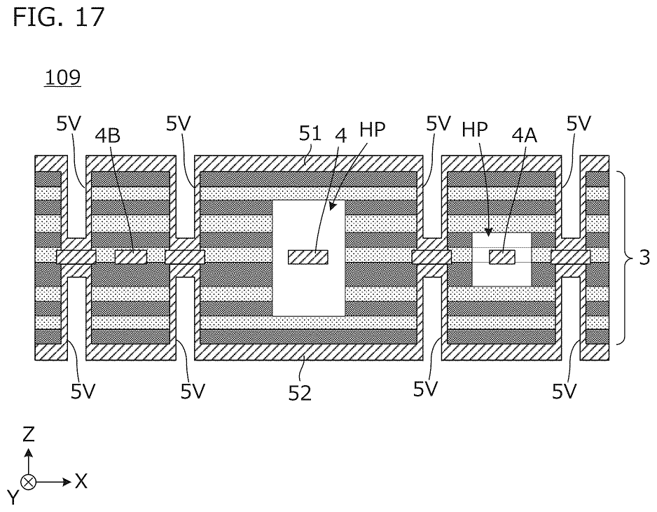

FIG. 17 is a longitudinal cross-sectional view of a high-frequency signal transmission line 109 according to the ninth example embodiment. The high-frequency signal transmission line 109 includes a resin stacked portion 3, signal conductor patterns 4 and 4A, a power supply conductor pattern 4B, a first ground conductor layer 51, a second ground conductor layer 52, and an interlayer connection conductor 5V.

In the high-frequency signal transmission line 109 illustrated in FIG. 17, two signal conductor patterns 4 and 4A and the power supply conductor pattern 4B are juxtaposed in a region separated by a plurality of interlayer connection conductors 5V arranged in the Y direction. The signal conductor pattern 4, the first ground conductor layer 51, the second ground conductor layer 52, and the interlayer connection conductor 5V provide a first high-frequency signal transmission line. The signal conductor pattern 4A, the first ground conductor layer 51, the second ground conductor layer 52, and the interlayer connection conductor 5V provide a second high-frequency signal transmission line. The power supply conductor pattern 4B, the first ground conductor layer 51, the second ground conductor layer 52, and the interlayer connection conductor 5V provide a power supply line.

For example, the first high-frequency signal transmission line is a line that transmits a 5G millimeter wave band RF signal, and the second high-frequency signal transmission line is a line that transmits a 5G Sub-6 band RF signal. The power supply line is a DC power supply line for driving an IC. Note that the power supply line may be, for example, a transmission line of a low-frequency signal such as a near field communication (NFC) signal.

In this manner, a high-frequency signal transmission line including a plurality of transmission lines or a high-frequency signal transmission line including a line for a direct current line may be configured.

An example of an electronic device will be described in the tenth example embodiment.

The high-frequency signal transmission line of the present invention can be used as a high-frequency signal transmission line in various electronic devices. For example, connectors are provided in the respective high-frequency circuits located on the two circuit boards, and for example, the coaxial connectors 61 and 62 of the high-frequency signal transmission line 103 illustrated in FIG. 4 are connected. The circuit board and the high-frequency signal transmission line 103 are housed in a housing with a predetermined shape. The electronic device is configured in this manner.

Finally, the present invention is not limited to each example embodiment described above. Modifications and alterations can be appropriately made by those skilled in the art. The scope of the present invention is defined not by the above-described example embodiments but by the claims. Further, the scope of the present invention includes modifications and alterations from the example embodiments within the scope equivalent to the claims.

For example, in each example embodiment, an example has been described in which the hollow portion HP extends in the upper, lower, left, and right directions (the X direction and the Z direction) in the direction orthogonal to the extending direction of the signal conductor pattern 4 (for example, the Y direction in FIG. 1), but the present invention is not limited thereto. For example, the hollow portion HP may extend only in the vertical direction (Z direction). The hollow portion HP may extend only in the left-right direction (X direction).

In each example embodiment, an example has been described in which not only the first resin layer includes a portion not in contact with the signal conductor pattern 4 but also the second resin layer 21 includes a portion not in contact with the signal conductor pattern 4, but the second resin layer 21 may be in contact with the signal conductor pattern 4. Since the second resin layer has a Young's modulus lower than that of the first resin layer, deformation of the ground conductor layer and the first resin layer is reduced or prevented even when the second resin layer 21 is in contact with the signal conductor pattern 4. When the second resin layer has a relative permittivity lower than that of the first resin layer, the spread of the electric field between the signal conductor pattern 4 and the interlayer connection conductor 5V is reduced or prevented even if the second resin layer 21 is in contact with the signal conductor pattern 4.

In addition, as described above, in each example embodiment, a single high-frequency signal transmission line is shown, but a large number of high-frequency signal transmission lines continuous in the plane direction may be manufactured up to the final process at the time of manufacturing and separated into the high-frequency signal transmission lines in the final process.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A high-frequency signal transmission line comprising:
a ground conductor layer;
a first resin layer;
a second resin layer; and
a signal conductor pattern; wherein
the ground conductor layer; the first resin layer; the second resin layer; and the signal conductor pattern are stacked in this order in a stacking direction, and a hollow portion is present between the signal conductor pattern and the second resin layer in a direction of the stacking; and
the first resin layer and the second resin layer are different in material, and a Young's modulus of the second resin layer is lower than a Young's modulus of the first resin layer.

2. The high-frequency signal transmission line according to claim 1, wherein
the ground conductor layer includes a first ground conductor layer and a second ground conductor layer existing on both sides of the signal conductor pattern in a direction of the stacking; and
the first resin layer and the second resin layer each exist on both sides of the signal conductor pattern in the stacking direction.

3. The high-frequency signal transmission line according to claim 2, further comprising:
an interlayer connection conductor that electrically connects the first ground conductor layer and the second ground conductor layer; wherein
the first ground conductor layer, the second ground conductor layer, the signal conductor pattern, and the interlayer connection conductor provide the high-frequency signal transmission line.

4. The high-frequency signal transmission line according to claim 3, wherein the interlayer connection conductor includes a protruding portion protruding outward from the first ground conductor layer and a protruding portion protruding outward from the second ground conductor layer.

5. The high-frequency signal transmission line according to claim 1, wherein the hollow portion extends in all of upper, lower, left, and right directions in a direction orthogonal to an extending direction of the signal conductor pattern.

6. The high-frequency signal transmission line according to claim 1, wherein a relative permittivity of the second resin layer is lower than a relative permittivity of the first resin layer.

7. The high-frequency signal transmission line according to claim 1, wherein
the first resin layer includes a polyimide, a liquid crystal polymer, or an epoxy resin; and
the second resin layer includes a thermoplastic polyimide, a fluorine-based resin, or a polyolefin-based resin.

8. The high-frequency signal transmission line according to claim 1, wherein an opening is located in the first resin layer and the second resin layer to define the hollow portion.

9. The high-frequency signal transmission line according to claim 1, wherein the first resin layer and the second resin layer are not in contact with the signal line conductor at the hollow portion.

10. The high-frequency signal transmission line according to claim 1, further comprising additional hollow portions in addition to the hollow portion.

11. The high-frequency signal transmission line according to claim 10, wherein a total of six hollow portions are provided.

12. The high-frequency signal transmission line according to claim 1, wherein the high-frequency signal transmission line is a microstrip line.

13. The high-frequency signal transmission line according to claim 10, wherein an interval between the hollow portions is less than about ¼ of a wavelength of a transmission signal transmitted by the high-frequency signal transmission line.

14. The high-frequency signal transmission line according to claim 1, further comprising a coaxial connector at each end of the high-frequency signal transmission line.

15. The high-frequency signal transmission line according to claim 1, wherein the signal conductor pattern and the ground conductor layer include a copper foil.

16. The high-frequency signal transmission line according to claim 1, wherein the high-frequency signal transmission line has a triplate configuration.

17. The high-frequency signal transmission line according to claim 1, wherein the first resin layer and the second resin layer are included in an upper resin stacked portion including a plurality of upper first resin layers and upper second resin layers.

18. The high-frequency signal transmission line according to claim 1, wherein the hollow portion exists above the signal conductor pattern.

19. The high-frequency signal transmission line according to claim 1, wherein the hollow portion exists above the signal conductor pattern and the hollow portion exists below the first resin layer.

20. An electronic device comprising the high-frequency signal transmission line according to claim 1.
